(19) United States
(12) Patent Application Publication
(10) Pub. No.: US 2024/0178797 A1
(43) Pub. Date: May 30, 2024

(54) AMPLIFICATION DEVICE AND AMPLIFICATION METHOD

(71) Applicant: Fujitsu Limited, Kawasaki-shi (JP)

(72) Inventor: HIDEHARU SHAKO, Yokohama (JP)

(73) Assignee: Fujitsu Limited, Kawasaki-shi (JP)

(21) Appl. No.: 18/235,445

(22) Filed: Aug. 18, 2023

(30) Foreign Application Priority Data
Nov. 29, 2022 (JP) 2022-190146

(51) Int. Cl. H03F 1/02; H03F 3/24

(52) U.S. Cl. CPC H03F 1/0288; H03F 3/245; H03F 2200/451

(57) ABSTRACT

An amplification device includes a peak amplifier and a carrier amplifier that are disposed in respective signal paths independently of each other. The amplification device further includes a measurement circuit that measures a transmission power for transmitting a radio signal obtained by combining an output signal from the peak amplifier and an output signal from the carrier amplifier, and a control circuit that performs control to turn off a first power supply of the peak amplifier in a case where a decrease in the transmission power is detected.

### CROSS-REFERENCE TO RELATED APPLICATION

This application is based upon and claims the benefit of priority of the prior Japanese Patent Application No. 2022-190146, filed on Nov. 29, 2022, the entire contents of which are incorporated herein by reference.

### FIELD

The embodiment discussed herein is related to an amplification device and an amplification method.

### BACKGROUND

Various techniques for reducing power consumption of a radio base station have been proposed.

Japanese Laid-open Patent Publication Nos. 2003-249885 and 2014-179737 are disclosed as related art.

An amplification device that amplifies a transmission power is used in a radio device used in a radio base station. It is known that the efficiency of the amplification device is highest in an output saturation state (nonlinear state). In the radio device, an amplification device including a Doherty type amplifier circuit may be used as an amplification device that achieves the highest efficiency in the output saturation state. The Doherty type amplifier circuit includes a peak amplifier (PA) and a carrier amplifier (CA) coupled in parallel.

In recent years, a communication service called “5th generation (5G)” (for example, “carrier 5G”), which is a mobile communication standard, has been proposed by communication business entities. A communication service called local 5G in which a business entity (for example, a manufacturer, a local government, or the like) other than the communication business entities may operate a network environment equivalent to a network environment of the 5G has been proposed. In the local 5G, the amplification device including the Doherty type amplifier circuit is used as in the case of the 5G.

### SUMMARY

According to an aspect of the embodiments, an amplification device includes: a peak amplifier and a carrier amplifier that are disposed in respective signal paths independently of each other; a measurement unit circuit that measures a transmission power for transmitting a radio signal obtained by combining an output signal from the peak amplifier and an output signal from the carrier amplifier; and a control unit circuit that performs control to turn off a first power supply of the peak amplifier in a case where a decrease in the transmission power is detected.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram illustrating an example of a radio base station;

FIG. 2 is a block diagram illustrating an example of an amplification device;

FIG. 3 is a diagram for describing an example of reduction in power consumption;

FIG. 4 is a processing sequence diagram illustrating an example of operations of a control device and a radio device; and

FIG. 5 is a table for describing an example of a reduction method.

### DESCRIPTION OF EMBODIMENTS

Since only specific users fewer than users of the communication service provided by the communication business entity use the communication service in the local 5G, in a case where a use frequency is low, power consumption may be systematically reduced. For example, there is room for further reduction in the power consumption in an amplification device used when the communication service of the 5G including the local 5G is provided.

Accordingly, in one aspect, it is an object to provide an amplification device and an amplification method that reduce power consumption.

An embodiment for carrying out the present disclosure will be described below with reference to the drawings.

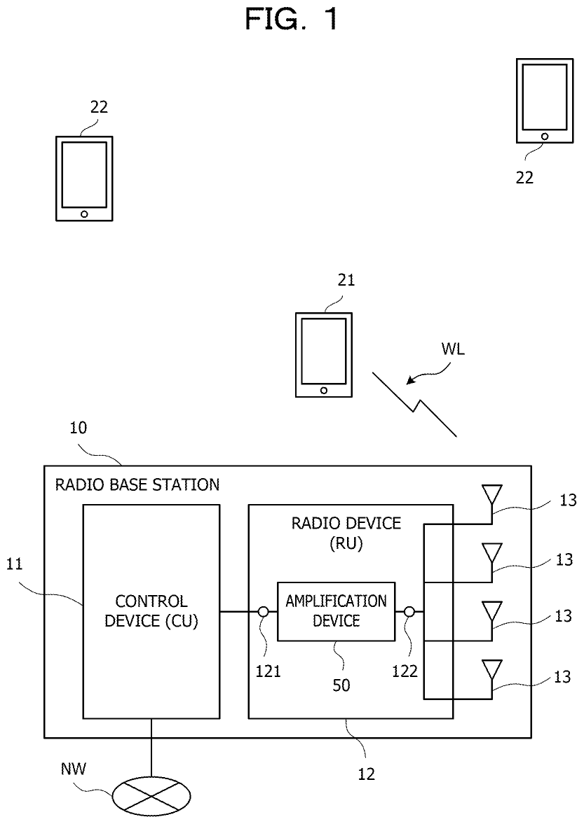

As illustrated in FIG. 1, a radio base station 10 includes a control device 11 and a radio device 12. In a carrier 5G or a local 5G, the control device 11 may be referred to as a centralized unit (CU), and the radio device 12 may be referred to as a radio unit (RU). For example, the control device 11 and the radio device 12 are coupled by an optical fiber. Transmission data is input to the control device 11 from a communication network NW. Examples of the communication network NW include a local area network (LAN), a core network (CN), the Internet, and the like.

The control device 11 executes predetermined baseband processing such as encoding of transmission data to generate a baseband transmission signal (hereafter, referred to as a baseband signal). The control device 11 outputs the generated baseband signal to the radio device 12. The radio device 12 converts the baseband signal input from the control device 11 into a transmission signal for radio communication (hereafter, referred to as a radio transmission signal).

After converting the baseband signal into a radio transmission signal, the radio device 12 performs various kinds of processing such as modulation, up-conversion, and amplification on the radio transmission signal. The radio device 12 transmits the radio transmission signal on which such processing has been performed, by using a radio WL via at least one of a plurality of antenna elements (hereafter, simply referred to as antennas) 13. The radio device 12 includes an amplification device 50. The amplification device 50 amplifies the radio transmission signal. The amplification device 50 is coupled to the control device 11 via an input terminal 121. The amplification device 50 is coupled to the plurality of antennas 13 via an output terminal 122.

A communication terminal 21 is a terminal device that receives the radio transmission signal transmitted from the antenna 13. A communication terminal 22 is a terminal device that does not receive the radio transmission signal transmitted from the antenna 13. The communication terminal 21 is an example of a first terminal device, and the communication terminal 22 is an example of a second terminal device. Although mobile terminals (for example, smartphones) are illustrated as an example of the communication terminals 21 and 22 in FIG. 1, the communication terminals 21 and 22 may be a tablet terminal, a wireless adapter of a personal computer (PC), or the like.

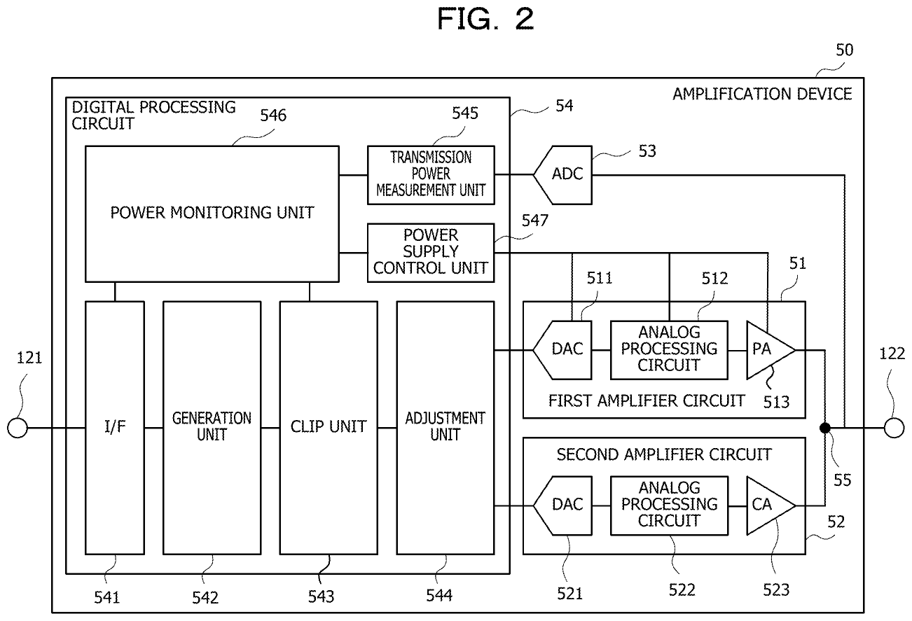

Details of the amplification device 50 will be described with reference to FIG. 2.

The amplification device 50 includes a first amplifier circuit 51, a second amplifier circuit 52, an analog-to-digital converter (ADC) 53, and a digital processing circuit 54. One end of each of the first amplifier circuit 51 and the second amplifier circuit 52 is coupled to the digital processing circuit 54. The other end of each of the first amplifier circuit 51 and the second amplifier circuit 52 is coupled to the output terminal 122.

The digital processing circuit 54 includes hardware circuits such as a field-programmable gate array (FPGA) and a memory. Instead of the FPGA, the digital processing circuit 54 may be a hardware circuit such as an application-specified integrated circuit (ASIC) or a central processing unit (CPU).

The digital processing circuit 54 includes an interface (referred to as I/F in FIG. 2) 541, a generation unit 542, a clip unit 543, and an adjustment unit 544. The digital processing circuit 54 includes a transmission power measurement unit 545, a power monitoring unit 546, and a power supply control unit 547. The power monitoring unit 546 and the power supply control unit 547 may be provided in the control device 11. The transmission power measurement unit 545 is an example of a measurement unit. The power monitoring unit 546 and the power supply control unit 547 are an example of a control unit.

The interface 541 receives the baseband signal output from the input terminal 121. The interface 541 may transmit a first control signal for controlling an operation of the control device 11 to the input terminal 121. The interface 541 may receive a second control signal for controlling an operation of the radio device 12 from the input terminal 121. The interface 541 may transmit, to the input terminal 121, the sent signal that is sent from the communication terminal 21 via the radio WL and is received by the radio device 12.

The generation unit 542 converts the baseband signal into a radio transmission signal. The clip unit 543 clips (regulates) an upper limit of an amplitude of the radio transmission signal based on a low power consumption mode number to be described later. The adjustment unit 544 generates, from the radio transmission signal, a first input signal to be used for a peak amplifier (hereafter, referred to as PA) 513 to be described later and a second input signal to be used for a carrier amplifier (hereafter, referred to as CA) 523 to be described later. The adjustment unit 544 individually generates the first input signal and the second input signal by adjusting an amplitude, a phase, and a delay of the radio transmission signal. The adjustment unit 544 inputs the first input signal to the first amplifier circuit 51. The adjustment unit 544 inputs the second input signal to the second amplifier circuit 52.

The first amplifier circuit 51 and the second amplifier circuit 52 are disposed in parallel. The first amplifier circuit 51 and the second amplifier circuit 52 are coupled to signal paths independent of each other and are thus duplicated. A Doherty type (more specifically, a digital Doherty type) amplifier circuit may be realized by the first amplifier circuit 51 and the second amplifier circuit 52. The digital processing circuit 54 may be included in the Doherty type amplifier circuit.

The first amplifier circuit 51 includes a digital-to-analog converter (DAC) 511, an analog processing circuit 512, and a PA 513. The analog processing circuit 512 is disposed between the DAC 511 and the PA 513. The DAC 511 and the analog processing circuit 512 are disposed at a previous stage of the PA 513. An input end of the DAC 511 is coupled to the digital processing circuit 54. An output end of the DAC 511 is coupled to the analog processing circuit 512. The PA 513 operates with a power supply voltage supplied from a power supply of the amplification device 50.

The DAC 511 converts the first input signal supplied from the adjustment unit 544, from a digital format to an analog format, and outputs the converted first input signal to the analog processing circuit 512. The analog processing circuit 512 executes processing such as modulation and up-conversion on the first input signal in the analog format, and outputs the first input signal to the PA 513. The PA 513 amplifies a power of the first input signal output from the analog processing circuit 512, and outputs the amplified first input signal as a first output signal. Since the upper limit of the amplitude of the radio transmission signal is clipped by the clip unit 543, the input of the first input signal having an amplitude equal to or greater than an output saturation point to the PA 513 is avoided.

The second amplifier circuit 52 includes a DAC 521, an analog processing circuit 522, and a CA 523. The analog processing circuit 522 is disposed between the DAC 521 and the CA 523. The DAC 521 and the analog processing circuit 522 are disposed at a previous stage of the CA 523. An input end of the DAC 521 is coupled to the digital processing circuit 54. An output end of the DAC 521 is coupled to the analog processing circuit 522. The CA 523 operates with the power supply voltage supplied from the power supply of the amplification device 50.

The DAC 521 converts the second input signal supplied from the adjustment unit 544, from a digital format to an analog format, and outputs the converted second input signal to the analog processing circuit 522. The analog processing circuit 522 executes processing such as modulation and up-conversion on the second input signal in the analog format, and outputs the second input signal to the CA 523. The CA 523 amplifies a power of the second input signal output from the analog processing circuit 522, and outputs the amplified second input signal as a second output signal.

An output end of the PA 513 and an output end of the CA 523 are coupled to each other. A coupling portion 55 of the two output ends is coupled to the output terminal 122. A signal path that couples the coupling portion 55 and the output terminal 122 is branched into two directions, one of the signal paths is coupled to the output terminal 122, and the other of the signal paths is coupled to the ADC 53.

Accordingly, the first output signal output from the PA 513 and the second output signal output from the CA 523 are combined at the coupling portion 55. Accordingly, a radio signal that is a signal obtained by combining the first output signal and the second output signal is input to each of the output terminal 122 and the ADC 53. The output terminal 122 outputs the input radio signal as the radio transmission signal to one of the plurality of antennas 13. The ADC 53 converts the radio signal from an analog format to a digital format and outputs the radio signal to the transmission power measurement unit 545.

The transmission power measurement unit 545 measures a transmission power for transmitting the radio signal. The power monitoring unit 546 monitors the transmission power of the radio signal measured by the transmission power measurement unit 545. In a case where the fact that the transmission power of the radio signal is lower than a threshold power for a certain time is detected, the power monitoring unit 546 transmits the first control signal to the control device 11 via the interface 541. The first control signal includes a power reduction request for reducing the power consumption of the amplification device 50.

The power monitoring unit 546 receives the second control signal from the control device 11 via the interface 541. The second control signal includes a low power consumption mode number corresponding to a usage state or the like of a radio communication resource (for example, a frequency, a resource block (RB), or the like). Although details will be described later, the control device 11 manages the usage state or the like of the radio communication resource, and specifies the low power consumption mode number corresponding to the usage state or the like. After receiving the second control signal, the power monitoring unit 546 changes an upper limit of an amplitude of the radio transmission signal clipped by the clip unit 543 based on a low power consumption mode number included in the second control signal.

After receiving the second control signal, the power monitoring unit 546 instructs the power supply control unit 547 to turn off a power supply of the first amplifier circuit 51. Accordingly, the power supply control unit 547 performs control to turn off the power supply of the first amplifier circuit 51. For example, the power supply control unit 547 performs control to turn off all of a first power supply that is a power supply for the PA 513, a second power supply that is a power supply for the DAC 511, and a third power supply that is a power supply for the analog processing circuit 512.

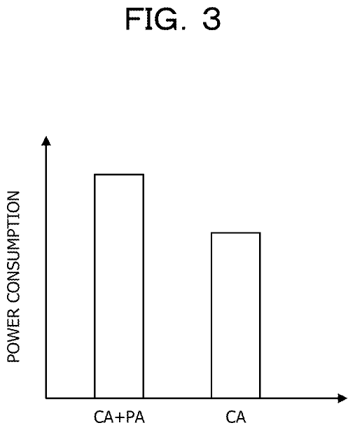

The power supply control unit 547 may independently turn off the first power supply of the PA 513. In this case, a state where a fourth power supply of the CA 523 is independently turned on is maintained. Since the fourth power supply of the CA 523 is independently turned on, it is possible to reduce the power consumption of the amplification device 50 as compared with a case where both of the first power supply of the PA 513 and the fourth power supply of the CA 523 are turned on, as illustrated in FIG. 3. For example, even though the first power supply is independently turned off, it is possible to reduce the power consumption of the amplification device 50.

However, since the second power supply of the DAC 511 and the third power supply of the analog processing circuit 512 are not turned off, power is consumed although the DAC 511 and the analog processing circuit 512 do not have to operate. For example, there is room for further reduction in power consumption. Thus, it is desirable that the power supply control unit 547 turns off not only the first power supply of the PA 513 but also the second power supply of the DAC 511 and the third power supply of the analog processing circuit 512. Even though the power supply control unit 547 performs control to turn off all of the first power supply of the PA 513, the second power supply of the DAC 511, and the third power supply of the analog processing circuit 512, the radio base station 10 may maintain a communication service.

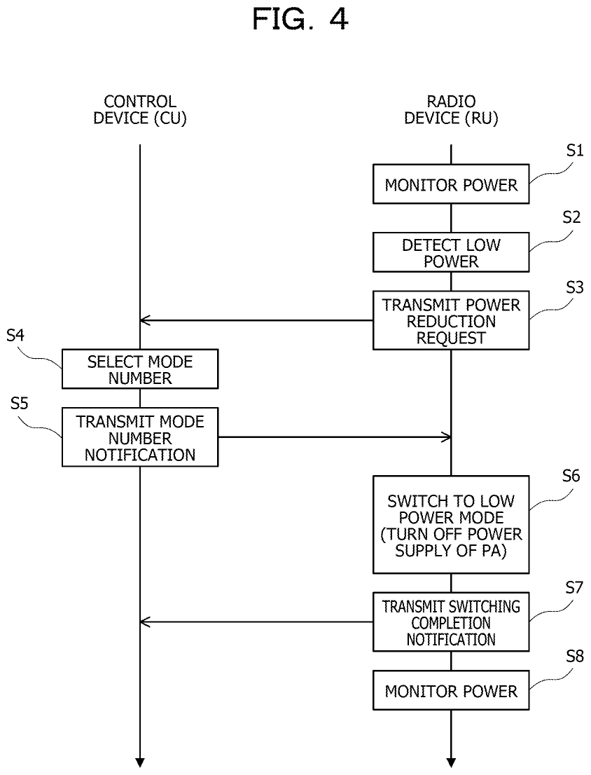

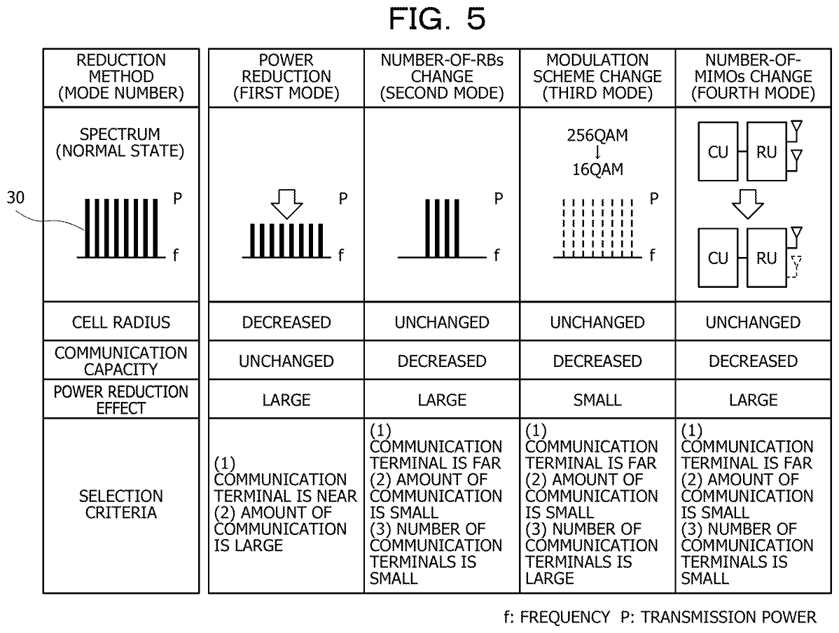

Next, operations of the control device 11 and the radio device 12 will be described below with reference to FIGS. 4 and 5.

First, as illustrated in FIG. 4, the power monitoring unit 546 of the radio device 12 monitors the transmission power of the radio signal measured by the transmission power measurement unit 545 (step S1). When the fact that the transmission power is lower than a threshold power for a threshold time is detected (step S2), the power monitoring unit 546 transmits the first control signal including the power reduction request to the control device 11 (step S3).

After receiving the first control signal, the control device 11 selects the low power consumption mode number (step S4). For example, as illustrated in FIG. 5, the control device 11 manages a first mode to a fourth mode as the low power consumption mode number (simply referred to as a mode number in FIG. 5), and selects one of the first mode to the fourth mode.

The first mode is a power reduction mode in which the transmission power of the radio transmission signal is reduced without reducing the number of RBs 30 to be used when the radio transmission signal is transmitted, compared with a transmission power in a normal state before the power supply of the first amplifier circuit 51 is turned off. According to the first mode, although a radius of the cell (cell radius) representing a coverage of the radio base station 10 is smaller than in the normal state, a communication capacity does not change. Since an area of a spectrum represented by a frequency and a transmission power in the first mode is smaller than that in the normal state, a large power reduction effect is obtained. Based on the usage state of the radio communication resource, in a case where it is determined that the communication terminal 21 is closer to the radio device 12 than the communication terminal 22 and the amount of communication is relatively large, the control device 11 selects the first mode.

The second mode is a number-of-RBs change mode in which the number of RBs 30 to be used when the radio transmission signal is transmitted is reduced from the number of RBs in the normal state without reducing the transmission power of the radio transmission signal as compared with the normal state. According to the second mode, as compared with the normal state, the cell radius does not change, but the communication capacity decreases. Because the area of the spectrum is smaller than that in the normal state in the second mode, a large power reduction effect is obtained. Based on the usage state of the radio communication resource, in a case where it is determined that the communication terminal 21 is farther from the radio device 12 than the communication terminal 22, the amount of communication for transmitting a radio transmission signal is relatively small, and the number of communication terminals 21 is smaller than the number of communication terminals 22, the control device 11 selects the second mode.

The third mode is a modulation scheme change mode in which a first modulation scheme of the radio device 12 is changed to a second modulation scheme that has a lower multilevel than a multilevel of the first modulation scheme. In the present embodiment, as an example, the first modulation scheme of “256 quadrature amplitude modulation (256QAM)” that has a multilevel of “256 values” is changed to the second modulation scheme of “16QAM” that has a multilevel of “16 values”. According to the third mode, as compared with the normal state, the cell radius does not change, but the communication capacity decreases. Although the area of the spectrum does not change in the third mode as compared with the normal state, since the modulation scheme is changed to the second modulation scheme that has a multilevel lower than the multilevel of the first modulation scheme, a small power reduction effect is obtained. Based on the usage state of the radio communication resource, in a case where it is determined that the communication terminal 21 is farther from the radio device 12 than the communication terminal 22, the amount of communication for transmitting the radio transmission signal is relatively small, and the number of the communication terminals 21 is larger than the number of communication terminals 22, the control device 11 selects the third mode.

The fourth mode is a multiple input multiple output (MIMO) mode in which the number of antennas 13 to be used when the radio transmission signal is transmitted is reduced from the number of antennas 13 in the normal state. According to the fourth mode, as compared with the normal state, the cell radius does not change, but the communication capacity decreases. Since the number of antennas 13 being operated is directly reduced in the fourth mode, a large power reduction effect is obtained. Based on the usage state of the radio communication resource, in a case where it is determined that the communication terminal 21 is farther from the radio device 12 than the communication terminal 22, the amount of communication for transmitting the radio transmission signal is relatively small, and the number of communication terminals 21 is smaller than the number of communication terminals 22, the control device 11 selects the fourth mode.

Referring back to FIG. 4, after selecting the low power consumption mode number, the control device 11 notifies the radio device 12 of the low power consumption mode number (step S5). For example, the control device 11 transmits the second control signal including the selected low power consumption mode number to the radio device 12. Accordingly, the power monitoring unit 546 of the radio device 12 receives the second control signal via the interface 541.

After the power monitoring unit 546 is notified of the low power consumption mode number, the power monitoring unit 546 switches the power supply control unit 547 from a normal mode to the low power consumption mode (step S6). For example, after receiving the second control signal, the power monitoring unit 546 instructs the power supply control unit 547 to turn off the power supply of the first amplifier circuit 51. Accordingly, the power supply control unit 547 performs control to turn off the first power supply of the PA 513. As described above, the power supply control unit 547 may perform control to turn off the second power supply of the DAC 511 and the third power supply of the analog processing circuit 512 together with the first power supply. For example, the normal mode is used during daytime when a large number of radio communication resources are requested. On the other hand, the low power consumption mode is used, for example, at night when the operation may be performed with a small amount of radio communication resources.

Along with turning off the power supply of the first amplifier circuit 51, the power monitoring unit 546 switches the clip unit 543 from the normal mode to any of the first mode to the fourth mode, based on the low power consumption mode number included in the received second control signal. Accordingly, the transmission power of the radio transmission signal is reduced together with the reduction in the power consumed by the first amplifier circuit 51. As described above, the power consumption of the radio device 12 may be significantly reduced as compared with a case where the power supply of the first amplifier circuit 51 is independently turned off.

In a time division duplex (TDD) scheme to be used in 5G, the power monitoring unit 546 switches the power supply control unit 547 from the normal mode to the low power consumption mode during a reception period of the sent signal sent as an uplink signal toward the radio base station 10 by the communication terminal 21. When the power supply control unit 547 is switched from the normal mode to the low power consumption mode during a transmission period of the radio transmission signal transmitted as a downlink signal toward the communication terminal 21 by the radio base station 10, a load of the PA 513 fluctuates. Accordingly, there is a possibility that a waveform of the radio transmission signal is distorted. During the reception period, since control of a transmission switch that switches the transmission of the radio transmission signal is turned off, an electrical burden on the amplification device 50 is small. At least the first power supply of the PA 513 is turned off while the communication service is maintained in such a situation.

After the switching from the normal mode to the low power consumption mode is completed, the power monitoring unit 546 transmits a switching completion notification to the control device 11 (step S7). The power monitoring unit 546 transmits the switching completion notification via the interface 541. After transmitting the switching completion notification, the power monitoring unit 546 monitors the power again (step S8). The power monitoring unit 546 monitors the power, and cancels the low power consumption mode in a case where a transmission power equal to or greater than the threshold power is detected at a high frequency.

In this case, the power monitoring unit 546 transmits the first control signal including a request to cancel the low power consumption mode to the control device 11, and receives the second control signal including an instruction to transition to the normal mode from the control device 11. After receiving this second control signal, the power monitoring unit 546 instructs the power supply control unit 547 to transition to the normal mode. Accordingly, the first amplifier circuit 51 is turned on. After receiving this second control signal, the power monitoring unit 546 switches the clip unit 543 from one of the first mode and the fourth mode to the normal mode. Accordingly, a large number of radio communication resources may be used.

As described above, the amplification device 50 according to the present embodiment includes the PA 513, the CA 523, the transmission power measurement unit 545, the power monitoring unit 546, and the power supply control unit 547. The PA 513 and the CA 523 are disposed in respective signal paths independent of each other. The transmission power measurement unit 545 measures a transmission power for transmitting a radio signal obtained by combining the first output signal from the PA 513 and the second output signal from the CA 523. When the power monitoring unit 546 detects a decrease in transmission power, the power supply control unit 547 performs control to turn off at least the first power supply of the PA 513. Accordingly, the power consumption of the amplification device 50 may be reduced, and as a result, the power consumption of the radio device 12 may be reduced.

According to the present embodiment, the first amplifier circuit 51 including the PA 513 and the second amplifier circuit 52 including the CA 523 are disposed in respective signal paths independent of each other and are thus duplicated. As described above, since the amplifier circuits are duplicated, the PA 513 and the CA 523 may be individually adjusted, but it is assumed that power consumption increases due to the duplication of the amplifier circuits. However, according to the present embodiment, the power supply of the first amplifier circuit 51 is turned off when amplification by the PA 513 is not to be performed. Accordingly, the power consumed independently by the CA 523 may be suppressed. A plurality of modes such as the first mode and the second mode described above are utilized, and thus, an adaptive power reduction method may be selected in accordance with the usage state of the radio communication resource.

Although the preferred embodiment of the present disclosure have been described in detail above, the present disclosure is not limited to the specific embodiment according to the present disclosure, and various modifications and changes may be made within a scope of the gist of the present disclosure described in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An amplification device comprising:
a peak amplifier and a carrier amplifier that are disposed in respective signal paths independently of each other;
a measurement circuit that measures a transmission power for transmitting a radio signal obtained by combining an output signal from the peak amplifier and an output signal from the carrier amplifier; and
a control circuit that performs control to turn off a first power supply of the peak amplifier in a case where a decrease in the transmission power is detected.

2. The amplification device according to claim 1, wherein
The control circuit performs control to turn off the first power supply in a case where the decrease in the transmission power is detected for a threshold time.

3. The amplification device according to claim 1, wherein
a digital-to-analog converter and a processing circuit that processes a signal output from the digital-to-analog converter are disposed at each of a previous stage of the peak amplifier and a previous stage of the carrier amplifier, and
the control circuit performs control to turn off a second power supply of the digital-to-analog converter on the peak amplifier side and a third power supply of the processing circuit on the peak amplifier side together with the first power supply.

4. The amplification device according to claim 1, wherein
the control circuit reduces the transmission power from a transmission power in a normal state before the control to turn off the first power supply is performed without reducing a number of resource blocks to be used when the radio signal is transmitted in a case where it is determined that a first terminal device that receives the radio signal is closer to a radio device that transmits the radio signal than a second terminal device that does not receive the radio signal.

5. The amplification device according to claim 1, wherein
the control circuit reduces a number of resource blocks to be used when the radio signal is transmitted from a number of resource blocks in a normal state before the control to turn off the first power supply is performed without reducing the transmission power in a case where it is determined that a first terminal device that receives the radio signal is farther from a radio device that transmits the radio signal than a second terminal device that does not receive the radio signal and a number of first terminal devices is smaller than a number of second terminal devices.

6. The amplification device according to claim 1, wherein
the control circuit reduces a number of antenna elements to be used when the radio signal is transmitted from a number of antenna elements in a normal state before the control to turn off the first power supply is performed in a case where it is determined that a first terminal device that receives the radio signal is farther from a radio device that transmits the radio signal than a second terminal device that does not receive the radio signal and a number of first terminal devices is smaller than a number of second terminal devices.

7. The amplification device according to claim 1, wherein
the control circuit changes a first modulation scheme of a radio device to a second modulation scheme that has a multilevel lower than a multilevel of the first modulation scheme in a case where it is determined that a first terminal device that receives the radio signal is farther from the radio device that transmits the radio signal than a second terminal device that does not receive the radio signal and a number of first terminal devices is larger than a number of second terminal devices.

8. The amplification device according to claim 1, wherein
the control circuit is included in one of a radio device that transmits the radio signal and a control device that controls the radio device.

9. The amplification device according to claim 1, wherein
the control unit performs control to turn off the first power supply during a period in which a sent signal sent from a terminal device that receives the radio signal is received.

10. An amplification method comprising:
measuring a transmission power for transmitting a radio signal obtained by combining an output signal from a peak amplifier and an output signal from the carrier amplifier, wherein the peak amplifier and the carrier amplifier are disposed in respective signal paths independently of each other; and
controlling to turn off a first power supply of the peak amplifier in a case where a decrease in the transmission power is detected.
